(19) United States
(12) Patent Application Publication
(10) Pub. No.: US 2010/0101631 A1
(43) Pub. Date: Apr. 29, 2010

(54) CONCENTRATION PHOTOVOLTAIC SYSTEM AND CONCENTRATION METHOD THEREOF

(75) Inventors: Roberto Battiston, Peugia (IT); Mauro Zenobi, Bastia Umbra (IT)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(73) Assignee: ANGELANTONI INDUSTRIE S.P.A., Massa Martana (IT)

(21) Appl. No.: 12/595,575

(22) PCT Filed: Apr. 11, 2008
(86) PCT No.: PCT/EP2008/054454

§ 371 Date: Oct. 12, 2009

(30) Foreign Application Priority Data
Apr. 12, 2007 (IT) PCT/IT2007/000273

(51) Int. Cl. H01L 31/052

(52) U.S. Cl. 136/246

(57) ABSTRACT

A concentration photovoltaic system (1,11) comprises lens-type concentrator means (2) for intercepting and concentrating beams of incident solar rays (4,114), and is characterized in that it comprises selection means (24,124), for selecting the frequencies of beams of solar rays entering the photovoltaic system (1,11), capable of direct selected rays towards a plurality of photovoltaic cells (12, 14, 16, 502, 602, 702). The invention also comprises a method for concentrating beams of incident solar rays (4, 114) which uses the concentration photovoltaic system described.

### TECHNICAL FIELD

The invention relates to a concentration photovoltaic system based on concentrator means for intercepting and concentrating beams of incident solar rays; the invention relates, moreover, to a method for concentrating solar energy on photovoltaic cells,

based on concentrator means for intercepting and concentrating beams of incident solar rays.

### PRIOR ART

As is well-known, photovoltaic systems comprise a certain number of photovoltaic cells which allow the reception and conversion of solar rays into energy, for example electrical energy, for the end use.

The most common photovoltaic systems are so-called “flat” photovoltaic systems in which the quantity of electrical energy produced is proportional to the surface area of the photovoltaic cells used; for this reason, these cells cover practically the whole of the surface of the panels exposed to the sun's rays, these surfaces necessarily having large dimensions in order to produce a quantity of energy which can be used in an efficient manner.

A serious drawback of these systems consists in the cost of the photovoltaic cells which represents most of the overall cost of a panel. The possibility of reducing the costs is therefore dependent almost exclusively on the reduction in the cost of the photovoltaic cells.

Research in this sector, which is not a new sector, could result in limited improvements and only at the expense of huge investments mainly in the technology of the cells.

An evolution in the photovoltaic systems consists in so-called “concentration” photovoltaic systems which use a concentrator device which intercepts the sun's rays and concentrates them on a photovoltaic cell having dimensions which are inversely proportional to the concentration factor of the concentrator device.

Concentration photovoltaic systems ensure a performance which is far superior to that of conventional flat photovoltaic systems, reduce the proportional cost of the cells and constitute a young technology with room for improvement and more extensive research.

A problem which is encountered, however, is that the concentration also results in raising of the temperature of the cells up to dangerous levels, so that suitable heat dissipators are nearly always envisaged.

Raising of the temperature is due to the fact that the quantity of photons (solar light) which causes the movement of electrons (electric power) is not high (low efficiency) and therefore many studies have been focussed on solutions for improving the photon-electron “conversion”.

One solution to this problem envisages the use of multi-joint cells, i.e. a type of multilayer photovoltaic cell which effectively increases in a significant manner the overall efficiency of the cell, allowing a lowering of the temperature. However, these cells are produced using costly and rare materials, such as germanium, and the technology is somewhat sophisticated, so that this solution is not easy to realise.

The patent application WO 2006/108806 in the name of Giuliano Martinelli et al., published on 19 Oct. 2006, is described a system which envisages dividing up the solar energy into two or more bands (dichroic, trichroic and more generally polychroic systems) by means of two or more coaxial reflector dishes, the first of which reflects the solar radiation with a certain spectral composition, allowing the remaining parts of the radiation to pass towards the other dishes.

In the case of two dishes, each of them reflects the portion of corresponding energy towards its own focal point which does not coincide with that of the other dish. The incoming solar energy is then divided into two beams which have a different spectral composition and an energy content equal to a fraction of the total incident energy even though obviously the sum of the energies associated with each beam corresponds to that prior to division.

This division has two effects:
it reduces the energy load on each cell for the same concentration factor;
it results in a higher efficiency in the photon/electron conversion process.

The overall result is that the amount of solar energy which is converted into electrical energy is higher and that the heat generated in each cell is reduced significantly.

The system described in the cited patent application, although it constitutes an improvement in terms of heat dissipation, has further defects:
the parabolic reflectors have an overall geometry which differs greatly from the mathematical area of the paraboloid and this gives rise to problems of a constructional nature which make mass-production difficult;
the entire surface of the parabolic dishes must incorporate within it the passband filter functions for the desired frequency band together with the non-passband reflection function;
owing to the significantly large dimensions, it is not possible to use easily low-cost technology such as plastics injection technology;
the cells are arranged on the focal points of the parabolic dishes with an arm which projects beyond the said dishes and which, by nature, is very delicate;
cleaning of the dishes which periodically must be performed in order to ensure the optimum efficiency of the system is difficult to perform with automatic systems which may be envisaged in large installations.
the whole system, in general, has a complex functioning and it is complex to carry out.

These defects make the system proposed difficult to apply on a large scale.

The object of the present invention is to provide a concentration photovoltaic system which is improved in terms of costs and manufacturing simplicity in order to overcome the drawbacks of the prior art.

### SUMMARY OF THE INVENTION

The object indicated above is achieved by a concentration photovoltaic system according to claim 1.

Moreover the present invention relates to a method for concentrating beams of incident solar rays on photovoltaic cells, according to claim 20

With the invention it is possible to achieve a significant improvement in the manufacturing costs and efficiency levels.

Lenses and cells are produced using conventional and low-cost technology.

The efficiency of the system is greater than the efficiency of the systems of the prior art.

The characteristic features and the further advantages of the invention will emerge from the description, provided hereinbelow, of an example of embodiment thereof provided purely by way of a non-limiting example with reference to the accompanying drawings.

### BRIEF DESCRIPTION OF THE DRAWINGS

FIG. 1 shows a partially cut-away perspective view of a photovoltaic system according to a first embodiment of the invention in the rest condition, namely in the condition where there is no solar radiation;

FIG. 2 shows the system according to FIG. 1 in the operating condition;

FIGS. 2a, 2b and 2c show details of the FIGS. 1 and 2.

FIG. 3 shows a partially cut-away perspective view of a photovoltaic system according to a second embodiment of the invention in the rest condition, namely in the condition where there is no solar radiation;

FIG. 4 shows the system according to FIG. 3 in the operating condition;

FIG. 5 shows a top plan view of the system according to FIGS. 3 and 4;

FIG. 6 shows a sectioned view of a detail of the system of the invention.

### DETAILED DESCRIPTION

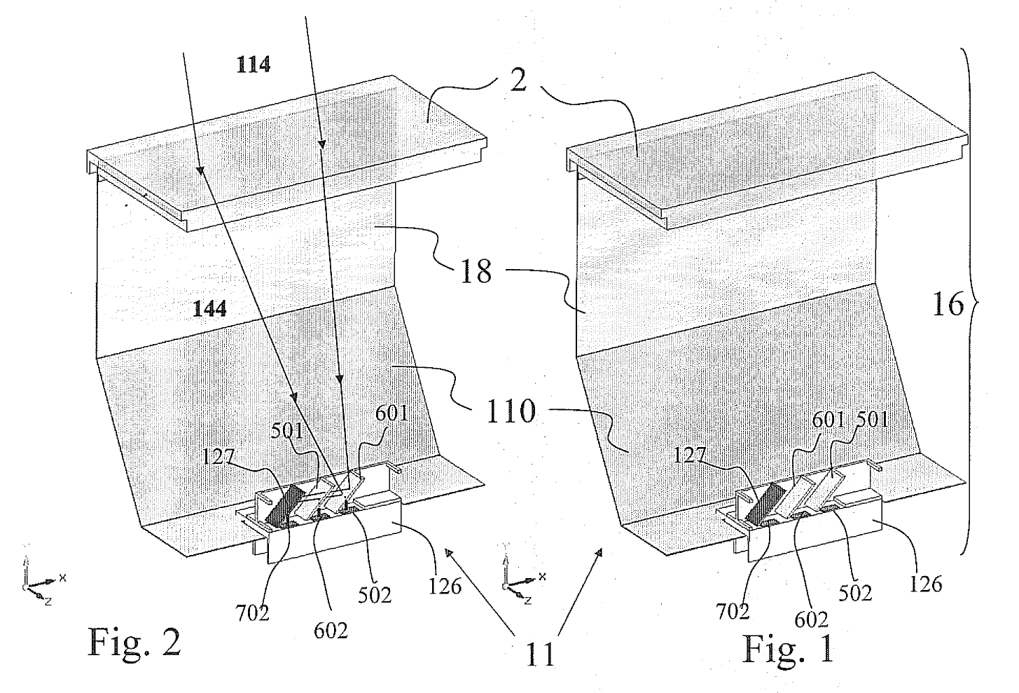

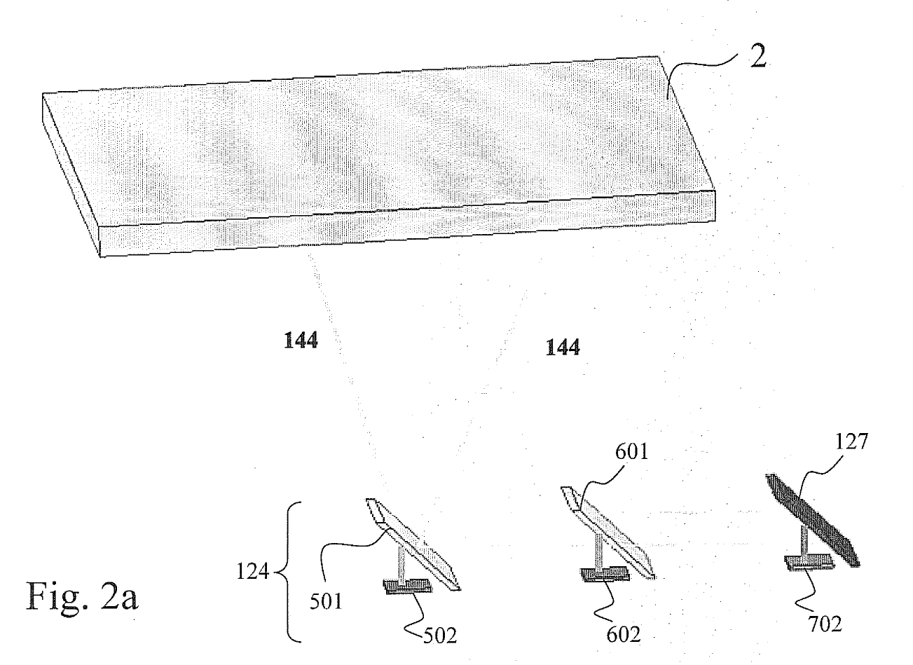

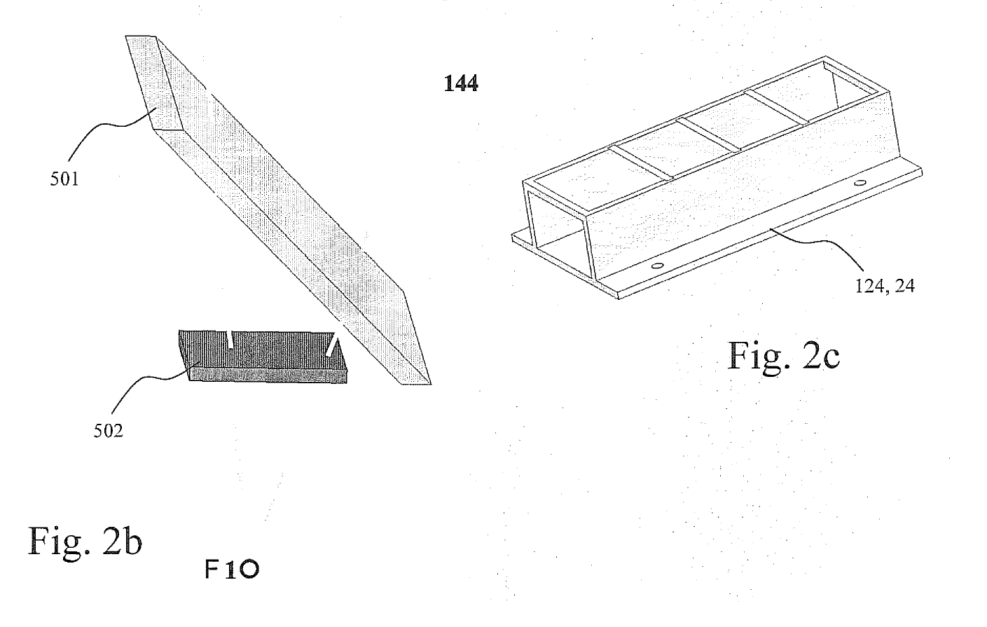

With reference to these Figures, in FIG. 1 a concentration photovoltaic system 1 comprises a container 16, only partially shown in FIGS. 1 and 2, preferably composed of a first portion 18, that rests, in the region of its inferior base, on a second portion 110, open in the region of its top base.

The first and second portions 18 and 110 may also have a frusto-pyramidal shape, a parallelepiped shape, frusto-conycal shape, or shapes which are similar to these.

The first portion 18 supports a first concentrator device 2, in particular a surface 2 for receiving and concentrating, without reflecting, beams of incident solar rays 14 (shown in FIG. 2).

According to the invention, the surface 2 is a lens, in particular a Fresnel lens, and may have different perimetral shapes, in particular a square or circular shape, corresponding to the shape of the first portion 18 of the container 16.

The container 16 therefore is a support for the Fresnel lens and for the other indicated components and protects and insulates all the components of the system.

The special feature of the Fresnel lens is that it, referring to the particular case of a circular lens shown in FIG. 6, performs the same function as a conventional semi-spherical lens of equivalent dioptric power that causes incident rays to converge in a point called focal point, with the advantage that it has a small thickness and weight; this lens is obtained by splitting up a conventional semi-spherical lens into a series of concentric annular sections called Fresnel rings, as shown in cross-section in FIG. 6, converting the continuous curve of a conventional semi-spherical lens into a series of surfaces 2a-2e which have the same curvature, but are radially not continuous.

The lens concentrates the incident and parallel solar ray beams 14 into beams of converging rays 144, as shown in FIGS. 2, 2a and 2b; in FIG. 2 is illustrated the same system as in FIG. 1, that shows specifically the paths of the solar rays 14 which strike the surface 2 and pass through it without being reflected.

According to the invention, the concentrator device 2 functions independently of the frequency of the incident solar rays 14. The beam of converging rays 144, therefore, is only a redirected and not an attenuated, filtered or reflected beam.

In the FIG. 2a, the system is shown from the opposite side with respect to FIG. 2, that is components 501, 601 and 701 are in reverse order.

Rays 144, according to the features of the surface 2, are redirected towards the focal point of the lenticular surface 2, as shown in FIG. 2b.

According to the first embodiment of the invention, converging rays 144 are directed towards means for selecting frequencies, that is a first filtering device 124 placed near the inferior base of the second portion 110. The filtering device 124 is placed above the focal point of the Fresnel lens thus converging rays 144 are stopped and redirected before reaching the focus F1 of the surface 2 (FIG. 2b).

The device 124 comprises (FIGS. 1, 2 and 2a)filtering optical elements, for instance two band-pass filters 501,601 to which two corresponding photovoltaic cells 502, 602 and a mirror 127 are coupled.

Band-pass filters are known per se; each transmits rays comprised in a certain frequency bandwidth (the band-pass frequency) and reflects rays at other frequencies.

Photovoltaic cells are known being portions of semiconductor material able to convert light radiations into electrical supply.

Since each semiconductor material is able to convert with high efficiency only in a specific frequency bandwidth, three different photovoltaic cells with three separated bandwidths have been used.

In the figures, the three cells used are similar; as a matter of the fact, the semiconductor material changes.

Specifically, a portion of the rays 144 with frequencies comprised in the band-pass, is transmitted from the first band-pass filter 501 towards the first photovoltaic cell 502, while the portion of the rays 144 non comprised in the band-pass is reflected towards a second band-pass filter 601; this reflects a part of the rays (those non comprised in the band-pass) towards a second photovoltaic cell 602 and transmits the other part of the rays (those comprised in the band-pass) towards the mirror 127 that, in turn, reflects them towards the third photovoltaic cell 702.

The system of the invention works in the whole solar spectrum (from 350 nm to 1800 nm); thus, the sum of the three bands of frequencies affected by the filtering optical elements 502,602 and by the other reflecting elements 127 is substantially the whole solar spectrum.

The filtering device lies on supporting elements 126 in turn fixed on a heat dissipater that has a first function of supporting the photovoltaic cells and it anchors the supporting elements for the band-pass filters and the mirror and a second function of discharging the heat generated into the photovoltaic cells.

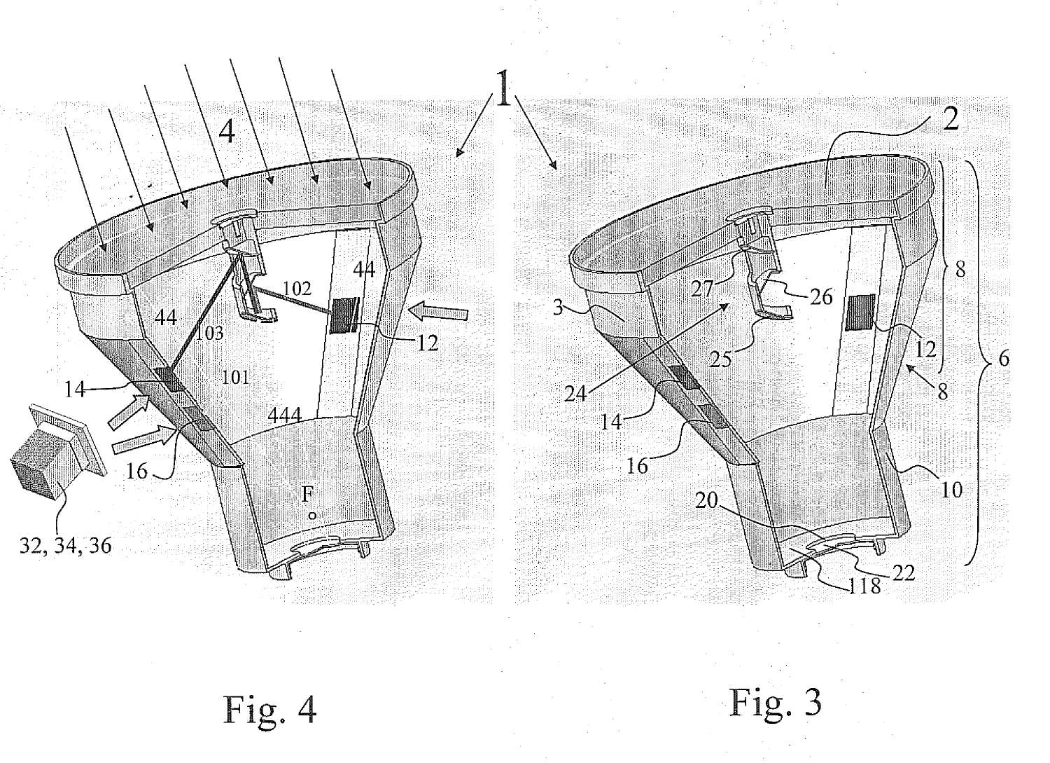

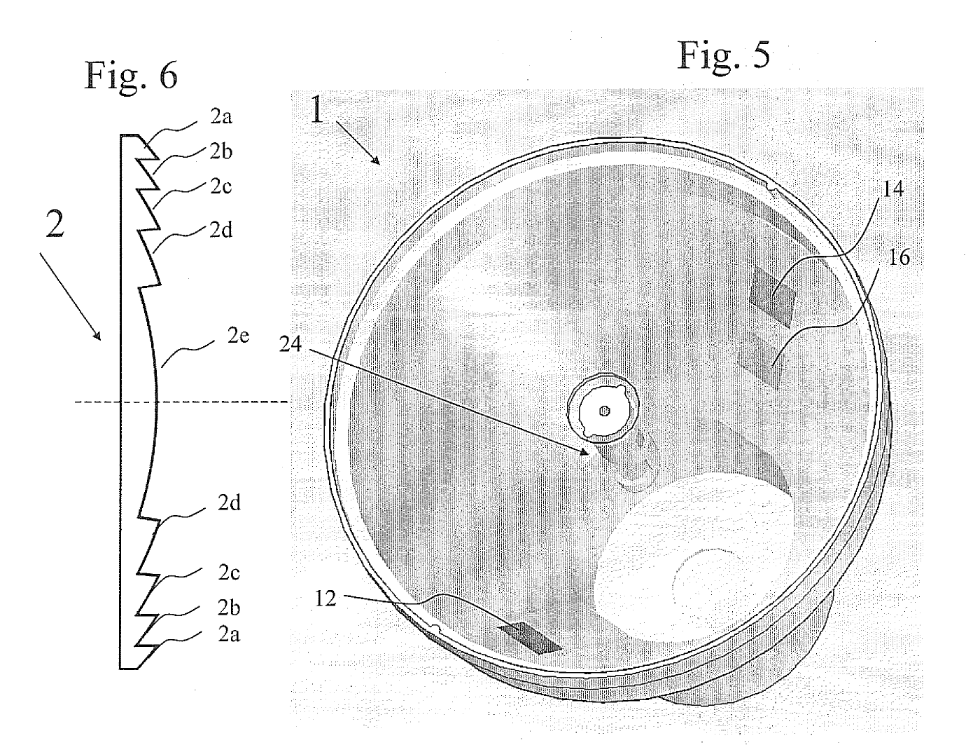

A second embodiment of the invention will be now described according to FIGS. 3-5 in which components similar to those of the first embodiment will maintain the same numbers and the same features of the described components (band-pass filters, mirrors, selection means).
A concentration photovoltaic system 1 comprises a container 16, preferably composed of a third portion 8, with a hollow frustoconical shape, open at both the bases and with the large base arranged at the top; this third portion 8 rests, in the region of its small base, on a fourth portion 10, which is preferably cylindrical, hollow, open in the region of its top base and provided with a hole in the bottom base 118; the portion 10 of the container 6 acts as support for the concentration photovoltaic system.

The third and fourth portions 8 and 10 may also have the same shape of the first and second portions of the first embodiment of the invention.

The third portion 8 has, in the region of its top base, a kind of flange 3 which supports a concentrator device 2, in particular a surface 2 for receiving and concentrating beams of incident solar rays 4 (shown in FIG. 4).

According to the invention, the surface 2 is a lens, in particular a Fresnel lens, and may have different perimetral shapes, in particular a square or circular shape, corresponding to the shape of the first portion 8 of the container 6.

The lens concentrates the incident and parallel solar ray beams 4 into converging ray beams 44, as shown in FIG. 4; such a figure illustrates the same system as in FIG. 3, that shows specifically the paths of the solar rays 4 which strike the surface 2 and pass through it without being reflected.

The bottom base 118 of the fourth portion 10 has a hole 20 where the converging ray beams 44 converge.

As for the first embodiment, the concentrator device 2 functions independently of the frequency of the incident solar rays 4. The beam of converging rays 44, therefore, is only a redirected and not an attenuated, filtered or reflected beam.

A parabolic mirror 22 with an upwardly directed concavity is mounted in the hole 20, the focal point F thereof, shown in FIG. 2, coinciding with the focal point of the Fresnel lens, namely the point towards which the beam of rays 44 converges.

The parabolic mirror 22 reflects the beam of converging rays 44, in the form of a beam of parallel rays 444, onto frequency selection means, that is a second filtering device 24 situated inside the container 6 and fixed along its axis within the third portion 8. The device 24 performs a division, according to predefined frequency intervals, of the beam of parallel rays 444 in the same way shown in the first embodiment.

The beam, which is divided up according to predefined frequencies, is directed towards a certain number of photovoltaic cells arranged, for example, on the side surface of the third portion 8.

The number of photovoltaic cells and the position thereof on the side surface of the third portion 8 second embodiment) or on the inferior base of the second portion 110 (first embodiment) depends on the manufacturing specifications and operation of the complete concentration photovoltaic system 1.

Special mirrors may be envisaged in place of the cells, said mirrors allowing reflection, where necessary, of the divided beam.

For the second embodiment of the invention (FIGS. 3-5), it is possible, therefore, to decide upon the lay-out, on the side surface, of the first portion 8 of the photovoltaic cells which may be, for example, opposite each other or arranged vertically alongside each other.

For the first embodiment of the invention (FIGS. 1-2) it is possible to decide upon the lay-out, on the inferior base, of the second portion 110 of the photovoltaic cells which may be, for example, appropriately spaced or side by side.

According to the preferred embodiments of the invention, three photovoltaic cells have been shown, only for an easier explanation.

The cells are designed especially to receive solar rays in a suitable frequency range and to optimize the energy produced on the basis of these frequencies. The number of band-pass filters and the characteristics of the photovoltaic cells onto which the rays are reflected are adjusted a priori on the basis of the division of the incident rays on the device 2 into predetermined frequency ranges, which can be selected as required, with a view to optimising the energy produced, maximising the efficiency of the system. In the technical jargon it is usually said that the photovoltaic cells are “tuned” to the frequencies of the reflected solar rays which they must receive. According to the second embodiment, depending on the concavity of the parabolic mirror 22, the position of the focal point of the parabolic dish, and consequently the amplitude of the beam of reflected rays 444, is determined, always with a view to maximising the efficiency of the system.

In both the embodiments, optionally, heat dissipators are envisaged and can be associated with the photovoltaic cells in order to reduce the operating temperature thereof. These dissipators are known per se, being liquid or air operated, and are situated outside the container so as not to affect in any way the ray beam passing inside the system.

Usually, this is not necessary since the energy density is divided up over several destination cells in a manner directly proportional to the number of cells, with a consequent reduction in the temperature.

Several concentration photovoltaic systems according to the invention may be easily coupled together and made to move in synchronism, but not integrally within a frame which also has small dimensions that can be installed on any type of horizontal or vertical surface, including roofs and facades of buildings.

In this way a further improvement in the efficiency is ensured on a large scale.

From the description provided hitherto it is possible to understand operation of the concentration photovoltaic system according to the present invention which operates using an innovative method for concentrating solar energy.

The concentrator device 2 is positioned so as to intercept solar rays as a beam of incident parallel solar rays 4,114. Owing to its intrinsic physical characteristics, this device causes the beam of solar rays to converge, independently of their frequency, in the form of a beam of concentrated solar rays 44,144.

In the first embodiment, the beam 144 is directed to a first band-pass filter 501. Rays incide on the first band-pass filter 501, upstream of the focus F1 of the concentrator device 2. The band-pass filter 501 transmits rays in the band-pass frequencies towards the first photovoltaic cell 502, while rays 144 non in the band-pass are reflected towards a second band-pass filter 601 that reflects rays not in a second bandwidth towards a second photovoltaic cell 602 and transmits rays in the band-pass towards a mirror 127 that reflects them towards a third photovoltaic cell 702.

In the second embodiment, rays 44 of the beam strike the parabolic mirror 22, downstream of the focal point F of the concentrator device 2. The focal point F of the Fresnel lens coincides with the focal point of the parabolic mirror 22.

The parabolic mirror reflects the concentrated solar rays 44 in the form of a beam of rays 444 which are again parallel, but have a diameter smaller than the beam of incident rays 4.

This beam 444, the diameter of which depends on the predefined requisites of the system, strikes the selection device 24, that work as the selection device 124. The rays of the band not in the band-pass of the two previous filters are reflected by means of the mirror 27 onto a last cell 14.

The energy is then extracted from the cells 12, 14, 16, 502, 602 and 702 for the end use.

1-14. (canceled)

15. A concentration photovoltaic system comprising:
concentrator means for intercepting beams of incident solar rays that strike and pass through said concentrator means and are concentrated, independently on the frequency, in beams of concentrated solar rays; and
means for the selection of frequencies comprising a plurality of filtering optical elements capable of selecting, according to predefined ranges, the frequencies of said beams of concentrated solar rays, and a plurality of photovoltaic cells receiving beams of said rays from said corresponding filtering optical elements, wherein
said filtering optical elements comprise band-pass filters wherein a first band-pass filter is capable of filtering rays in a first range of frequencies, reflecting them towards a second band-pass filter, non reflected rays being capable of being transmitted towards a first photovoltaic cells, and wherein a second band-pass filter is capable of filtering rays in a second range of frequencies, non reflected rays being capable of being transmitted towards a second photovoltaic cell.

16. The concentration photovoltaic system according to claim 15, wherein said selection means comprise a third photovoltaic cell capable of receiving rays from corresponding reflecting optical elements.

17. The concentration photovoltaic system according to claim 16, wherein said reflecting optical element comprise a mirror capable of reflecting said beams of concentrated solar rays, not previously reflected from said plurality of band-pass filters, towards a photovoltaic cell.

18. The concentration photovoltaic system according to claim 15, in which beams of incident solar rays are beams of parallel straight rays.

19. The concentration photovoltaic system according to claim 15, wherein said concentrator means are of the lens type.

20. The concentration photovoltaic system according to claim 19, wherein said concentrator means comprise a Fresnel lens.

21. The concentration photovoltaic system according to claim 15, wherein said beams of concentrated rays are beams of straight rays directed to the focal point of said concentrator means.

22. The concentration photovoltaic system according to claim 21, wherein said focal point is the focal point of a Fresnel lens.

23. The concentration photovoltaic system according to claim 22, wherein said focal point is placed below said selection means and not reached from said rays.

24. The concentration photovoltaic system according to claim 15, comprising a supporting elements supporting the selection means and fixed on a heat dissipater capable of discharging the heat generated into the photovoltaic cells.

25. A method for concentrating beams of solar rays striking photovoltaic cells, which uses the concentration photovoltaic system according to claim 15, comprising the steps of:
intercepting beams of incident solar rays by means of concentrator means that strike and pass through said concentrator means and are concentrated, independently of the frequency, in concentrated solar rays beams; and
selecting, according to predefined frequencies ranges, said beams of concentrated solar rays, by means of selection means comprising a plurality of band-pass filters wherein a first band-pass filter is capable of filtering rays in a first range of frequencies, reflecting them towards a second band-pass filter, non reflected rays being capable of being transmitted towards a first photovoltaic cells, and wherein a second band-pass filter is capable of filtering rays in a second range of frequencies, non reflected rays being capable of being transmitted towards a second photovoltaic cell.

26. The method according to claim 25, wherein the second band-pass filter transmits rays in the band-pass towards a mirror.

27. The method according to claim 25, wherein said mirror reflects towards a third photovoltaic cell rays in the range of frequencies in the band-pass frequency.

28. The method according to claim 25, wherein said cells convert the received solar rays into energy for the end use.
